(19) United States
(12) Patent Application Publication
(10) Pub. No.: US 2026/0255608 A1
(43) Pub. Date: Aug. 27, 2026

(54) SEMICONDUCTOR MEMORY DEVICE

(71) Applicant: Kioxia Corporation, Tokyo (JP)

(72) Inventors: Takeo KOIKE, Seoul (KR); Hiroyuki KANAYA, Yokohama (JP)

(73) Assignee: Kioxia Corporation, Tokyo (JP)

(21) Appl. No.: 19/314,887

(22) Filed: Aug. 29, 2025

(30) Foreign Application Priority Data
Feb. 21, 2025 (JP) 2025-026962

(51) Int. Cl. H10B 61/00; H10N 50/01; H10N 50/10

(52) U.S. Cl. CPC H10B 61/10; H10N 50/01; H10N 50/10

(57) ABSTRACT

A semiconductor memory device includes first wirings extending in a first direction; second wirings extending in a second direction; memory cells provided between the first wirings and the second wirings and arranged in the first or second direction, each of the memory cells including a corresponding variable resistance element and a corresponding selector, the selectors each configured to switch a current flowing to the corresponding variable resistance element; and a first insulating film provided between the memory cells. The first wirings are each provided between adjacent ones of the variable resistance elements in the first direction, or the second wirings are each provided between adjacent ones of the plurality of variable resistance elements arranged in the second direction.

### CROSS-REFERENCE TO RELATED APPLICATION

This application is based upon and claims the benefit of priority from Japanese Patent Application No. 2025-026962, filed Feb. 21, 2025, the entire contents of which are incorporated herein by reference.

### FIELD

Embodiments described herein relate generally to a semiconductor memory device.

### BACKGROUND

Semiconductor memory devices using variable resistance storage elements are known. In such semiconductor memory devices, there is a problem of deterioration due to heat generation.

### DESCRIPTION OF THE DRAWINGS

FIG. 1 is a block diagram illustrating a configuration example of a semiconductor memory device according to a first embodiment;

FIG. 2 is a circuit diagram illustrating a configuration of a memory cell array of the semiconductor memory device according to the first embodiment;

FIG. 3A is a cross-sectional view illustrating a configuration of a memory cell of the semiconductor memory device according to the first embodiment;

FIG. 3B is a cross-sectional view illustrating the configuration of the memory cell of the semiconductor memory device according to the first embodiment;

FIG. 4 is a cross-sectional view illustrating a configuration of a memory cell of a semiconductor memory device according to a modification of the first embodiment;

FIG. 5 is a cross-sectional view illustrating a configuration of a memory cell of a semiconductor memory device according to another modification of the first embodiment;

FIG. 6 is a cross-sectional view illustrating a configuration example of one magnetoresistive effect element;

FIG. 7A is a diagram illustrating an example of a method of manufacturing the semiconductor memory device according to the first embodiment;

FIG. 7B is a diagram illustrating an example of the method of manufacturing the semiconductor memory device according to the first embodiment;

FIG. 7C is a diagram illustrating an example of the method of manufacturing the semiconductor memory device according to the first embodiment;

FIG. 8A is a diagram following FIG. 7A and illustrating an example of the method of manufacturing the semiconductor memory device;

FIG. 8B is a diagram following FIG. 7B and illustrating an example of the method of manufacturing the semiconductor memory device;

FIG. 8C is a diagram following FIG. 7C and illustrating an example of the method of manufacturing the semiconductor memory device;

FIG. 9A is a diagram following FIG. 8A and illustrating an example of the method of manufacturing the semiconductor memory device;

FIG. 9B is a diagram following FIG. 8B and illustrating an example of the method of manufacturing the semiconductor memory device;

FIG. 9C is a diagram following FIG. 8C and illustrating an example of the method of manufacturing the semiconductor memory device;

FIG. 10A is a diagram following FIG. 9A and illustrating an example of the method of manufacturing the semiconductor memory device;

FIG. 10B is a diagram following FIG. 9B and illustrating an example of the method of manufacturing the semiconductor memory device;

FIG. 10C is a diagram following FIG. 9C and illustrating an example of the method of manufacturing the semiconductor memory device;

FIG. 11A is a diagram following FIG. 10A and illustrating an example of the method of manufacturing the semiconductor memory device;

FIG. 11B is a diagram following FIG. 10B and illustrating an example of the method of manufacturing the semiconductor memory device;

FIG. 11C is a diagram following FIG. 10C and illustrating an example of the method of manufacturing the semiconductor memory device;

FIG. 12A is a diagram following FIG. 11A and illustrating an example of the method of manufacturing the semiconductor memory device;

FIG. 12B is a diagram following FIG. 11B and illustrating an example of the method of manufacturing the semiconductor memory device;

FIG. 12C is a diagram following FIG. 11C and illustrating an example of the method of manufacturing the semiconductor memory device;

FIG. 13A is a diagram following FIG. 12A and illustrating an example of the method of manufacturing the semiconductor memory device;

FIG. 13B is a diagram following FIG. 12B and illustrating an example of the method of manufacturing the semiconductor memory device;

FIG. 13C is a diagram following FIG. 12C and illustrating an example of the method of manufacturing the semiconductor memory device;

FIG. 14A is a diagram following FIG. 13A and illustrating an example of the method of manufacturing the semiconductor memory device;

FIG. 14B is a diagram following FIG. 13B and illustrating an example of the method of manufacturing the semiconductor memory device;

FIG. 14C is a diagram following FIG. 13C and illustrating an example of the method of manufacturing the semiconductor memory device;

FIG. 15A is a diagram following FIG. 14A and illustrating an example of the method of manufacturing the semiconductor memory device;

FIG. 15B is a diagram following FIG. 14B and illustrating an example of the method of manufacturing the semiconductor memory device;

FIG. 15C is a diagram following FIG. 14C and illustrating an example of the method of manufacturing the semiconductor memory device;

FIG. 16 is a cross-sectional view illustrating a configuration of a memory cell of a semiconductor memory device according to a second embodiment;

FIG. 17 is a cross-sectional view illustrating a configuration of a memory cell of a semiconductor memory device according to a third embodiment;

FIG. 18 is a cross-sectional view illustrating a configuration of the memory cell of the semiconductor memory device according to the third embodiment;

FIG. 19 is a cross-sectional view illustrating a configuration of a memory cell of a semiconductor memory device according to a modification of the third embodiment;

FIG. 20A is a diagram illustrating an example of a method of manufacturing the semiconductor memory device according to the third embodiment;

FIG. 20B is a diagram illustrating an example of a method of manufacturing the semiconductor memory device according to the third embodiment;

FIG. 20C is a diagram illustrating an example of a method of manufacturing the semiconductor memory device according to the third embodiment;

FIG. 21A is a diagram following FIG. 20A and illustrating an example of the method of manufacturing the semiconductor memory device;

FIG. 21B is a diagram following FIG. 20B and illustrating an example of the method of manufacturing the semiconductor memory device;

FIG. 21C is a diagram following FIG. 20C and illustrating an example of the method of manufacturing the semiconductor memory device;

FIG. 22A is a diagram following FIG. 21A and illustrating an example of the method of manufacturing the semiconductor memory device;

FIG. 22B is a diagram following FIG. 21B and illustrating an example of the method of manufacturing the semiconductor memory device;

FIG. 22C is a diagram following FIG. 21C and illustrating an example of the method of manufacturing the semiconductor memory device;

FIG. 23A is a diagram following FIG. 22A and illustrating an example of the method of manufacturing the semiconductor memory device;

FIG. 23B is a diagram following FIG. 22B and illustrating an example of the method of manufacturing the semiconductor memory device;

FIG. 23C is a diagram following FIG. 22C and illustrating an example of the method of manufacturing the semiconductor memory device;

FIG. 24A is a diagram following FIG. 23A and illustrating an example of the method of manufacturing the semiconductor memory device;

FIG. 24B is a diagram following FIG. 23B and illustrating an example of the method of manufacturing the semiconductor memory device;

FIG. 24C is a diagram following FIG. 23C and illustrating an example of the method of manufacturing the semiconductor memory device;

FIG. 25A is a diagram following FIG. 24A and illustrating an example of the method of manufacturing the semiconductor memory device;

FIG. 25B is a diagram following FIG. 24B and illustrating an example of the method of manufacturing the semiconductor memory device;

FIG. 25C is a diagram following FIG. 24C and illustrating an example of the method of manufacturing the semiconductor memory device;

FIG. 26A is a diagram following FIG. 25A and illustrating an example of the method of manufacturing the semiconductor memory device;

FIG. 26B is a diagram following FIG. 25B and illustrating an example of the method of manufacturing the semiconductor memory device;

FIG. 26C is a diagram following FIG. 25C and illustrating an example of the method of manufacturing the semiconductor memory device;

FIG. 27A is a diagram following FIG. 26A and illustrating an example of the method of manufacturing the semiconductor memory device;

FIG. 27B is a diagram following FIG. 26B and illustrating an example of the method of manufacturing the semiconductor memory device;

FIG. 27C is a diagram following FIG. 26C and illustrating an example of the method of manufacturing the semiconductor memory device;

FIG. 28A is a diagram following FIG. 27A and illustrating an example of the method of manufacturing the semiconductor memory device;

FIG. 28B is a diagram following FIG. 27B and illustrating an example of the method of manufacturing the semiconductor memory device;

FIG. 28C is a diagram following FIG. 27C and illustrating an example of the method of manufacturing the semiconductor memory device;

FIG. 29A is a diagram following FIG. 28A and illustrating an example of the method of manufacturing the semiconductor memory device;

FIG. 29B is a diagram following FIG. 28B and illustrating an example of the method of manufacturing the semiconductor memory device; and

FIG. 29C is a diagram following FIG. 28C and illustrating an example of the method of manufacturing the semiconductor memory device.

### DETAILED DESCRIPTION

Embodiments provide a semiconductor memory device that prevents deterioration due to heat generation and has high reliability.

In general, according to one embodiment, a semiconductor memory device includes: a plurality of first wirings extending in a first direction; a plurality of second wirings extending in a second direction intersecting the first direction; a plurality of memory cells provided between the plurality of first wirings and the plurality of second wirings and arranged in the first or second direction, each of the memory cells including a corresponding one of a plurality of variable resistance elements and a corresponding one of a plurality of selectors, the selectors each configured to switch a current flowing to the corresponding variable resistance element; and a first insulating film provided between the plurality of memory cells. The first wirings are each provided between adjacent ones of the variable resistance elements in the first direction, or the second wirings are each provided between adjacent ones of the plurality of variable resistance elements arranged in the second direction.

Hereinafter, embodiments will be described with reference to the drawings. The embodiments are not limited to the present disclosure. The drawings are schematic or conceptual. In the present specification and the drawings, the same reference numerals are given to the same elements.

### First Embodiment

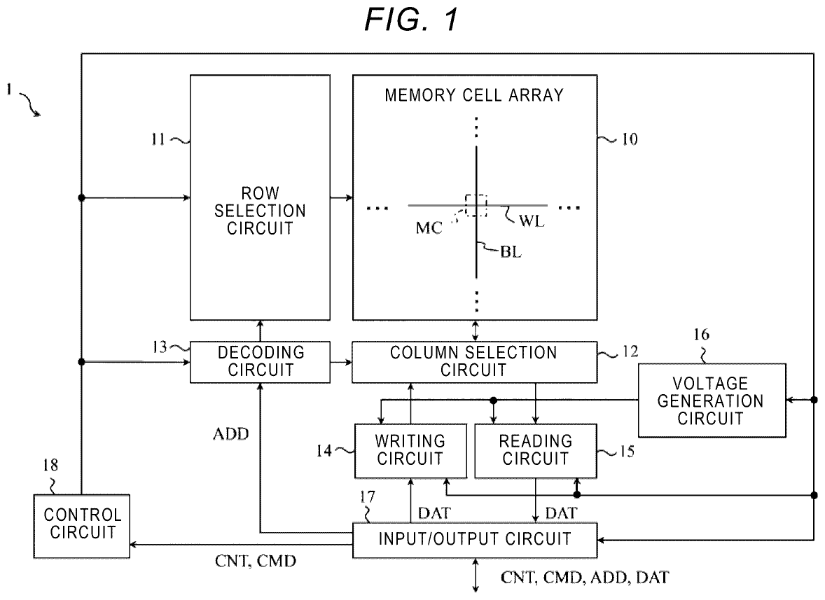

FIG. 1 is a block diagram illustrating a configuration example of a semiconductor memory device 1 according to a first embodiment. The semiconductor memory device 1 according to the first embodiment is, for example, a perpendicular magnetization type magnetic storage device in which a magnetic tunnel junction (MTJ) element having a magnetoresistive effect by MTJ is used as a variable resistance element. The embodiments can also be applied to other variable resistance elements such as a phase change memory (PCM). In the following description, a magnetic storage device will be described as an example of a semiconductor memory device.

The semiconductor memory device 1 includes a memory cell array 10, a row selection circuit 11, a column selection circuit 12, a decoding circuit 13, a writing circuit 14, a reading circuit 15, a voltage generation circuit 16, an input/output circuit 17, and a control circuit 18.

The memory cell array 10 includes a plurality of memory cells MC associated with intersections of rows and columns. The memory cells MC in the same row are connected to the same word line WL and the memory cells MC in the same column are connected to the same bit line BL.

The row selection circuit 11 is connected to the memory cell array 10 via a word line WL. A decoding result (row address) of an address ADD from the decoding circuit 13 is supplied to the row selection circuit 11. The row selection circuit 11 sets the word line WL corresponding to a row based on the decoding result of the address ADD to a selected state. Hereinafter, the word line WL set to the selected state is referred to as a selected word line WL. The word lines WL other than the selected word line WL are referred to as non-selected word lines WL.

The column selection circuit 12 is connected to the memory cell array 10 via a bit line BL. A decoding result (column address) of the address ADD from the decoding circuit 13 is supplied to the column selection circuit 12. The column selection circuit 12 sets the bit line BL corresponding to a column based on the decoding result of the address ADD to a selected state. Hereinafter, the bit line BL set to the selected state is referred to as a selected bit line BL. The bit lines BL other than the selected bit line BL are referred to as non-selected bit lines BL.

The decoding circuit 13 decodes the address ADD transmitted from the input/output circuit 17. The decoding circuit 13 supplies the decoding result of the address ADD to the row selection circuit 11 and the column selection circuit 12. The address ADD includes the column address and the row address to be selected.

The writing circuit 14 writes data into the memory cell MC. The writing circuit 14 includes, for example, a writing driver.

The reading circuit 15 reads data from the memory cell MC. The reading circuit 15 includes, for example, a sense amplifier.

The voltage generation circuit 16 generates voltages for various operations of the memory cell array 10 using a power voltage supplied from outside of the semiconductor memory device 1. For example, the voltage generation circuit 16 generates various voltages necessary during a write operation and outputs the generated voltages to the writing circuit 14. For example, the voltage generation circuit 16 generates various voltages necessary during a read operation and outputs the generated voltages to the reading circuit 15.

The input/output circuit 17 transmits the address ADD from outside of the semiconductor memory device 1 to the decoding circuit 13. The input/output circuit 17 transmits a command CMD from outside of the semiconductor memory device 1 to the control circuit 18. The input/output circuit 17 transmits and receives various control signals CNT between outside of the semiconductor memory device 1 and the control circuit 18. The input/output circuit 17 transmits data DAT from outside of the semiconductor memory device 1 to the writing circuit 14 and outputs the data DAT transmitted from the reading circuit 15 to outside of the semiconductor memory device 1.

The control circuit 18 controls operations of the row selection circuit 11, the column selection circuit 12, the decoding circuit 13, the writing circuit 14, the reading circuit 15, the voltage generation circuit 16, and the input/output circuit 17 in the semiconductor memory device 1 based on the control signal CNT and the command CMD.

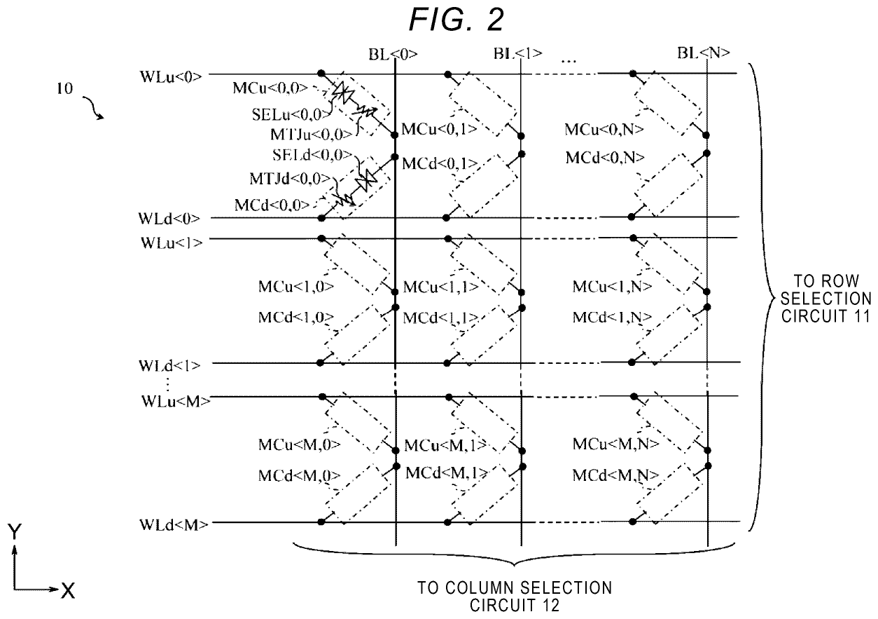

FIG. 2 is a circuit diagram illustrating a configuration of a memory cell array of the semiconductor memory device according to the first embodiment. The memory cells MC (MCu and MCd) are two-dimensionally arranged in a matrix configuration in the memory cell array 10 and are associated with an intersection between one bit line among a plurality of bit lines BL (BL<0>, BL<1>, . . . , BL<N>) and one word line among a plurality of word lines WLd (WLd<0>, WLd<1>, . . . , WLd(M>) and WLu (WLu<0>, WLu<1>, . . . , and WLu<M>) (M and N are any integer). That is, a memory cell MCd<i, j> (0≤i≤M and 0≤j≤N) is connected between a word line WLd<i> and a bit line BL<j>. A memory cell MCu<i, j> is connected between a word line WLu<i> and the bit line BL<j>. The word lines WLu and WLd intersect the bit line BL, and for example, are orthogonal to the bit line BL. Hereinafter, the word lines WLu and WLd are collectively referred to as the word lines WL. The memory cells MCu and MCd are collectively referred to as the memory cells MC.

Here, d in WLd or the like indicates a configuration provided below the bit line BL for convenience. u in WLu or the like indicates a configuration provided above the bit line BL for convenience.

The plurality of word lines WL extend in the X direction and are arranged in the Y direction. The plurality of memory cells MC are arranged in the X direction along the plurality of word lines WL. The plurality of bit lines BL extend in the Y direction and are arranged in the X direction. The plurality of memory cells MC are arranged in the Y direction along the plurality of bit lines BL. As such, the plurality of memory cells MC are two-dimensionally arranged on an X-Y plane.

The memory cell MCd<i, j> includes a selector SELd<i, j> and a magnetoresistive effect element MTJd<i, j> connected in series between the corresponding word line WL and the corresponding bit line BL. The memory cell MCu<i, j> includes a selector SELu<i, j> and a magnetoresistive effect element MTJu<i, j> connected in series.

The selector SEL has a function as a switch that controls supply of a current flowing to the magnetoresistive effect element MTJ during writing and reading of data in and from the magnetoresistive effect element MTJ. For example, the selector SEL in a certain memory cell MC serves as an insulator having a large resistance value and cuts off (turns off) a current when a voltage applied to the memory cell MC is less than a threshold voltage Vth. The selector SEL serves as a conductor having a small resistant value and flows (turns on) a current when a voltage applied to the memory cell MC is the threshold voltage Vth or more. That is, the selector SEL switches between flow and cutoff of current according to a magnitude of voltage difference (voltage applied to the memory cell MC) between the corresponding word line WL and bit line BL regardless of a direction of a flowing current.

The magnetoresistive effect element MTJ is switched between a low resistance state and a high resistance state according to a current from the selector SEL. The magnetoresistive effect element MTJ can write data according to a change in the resistance state and can store and read the data in a nonvolatile manner. As such, the magnetoresistive effect element MTJ functions as a storage element.

Next, a cross-sectional structure of the memory cell array 10 will be described.

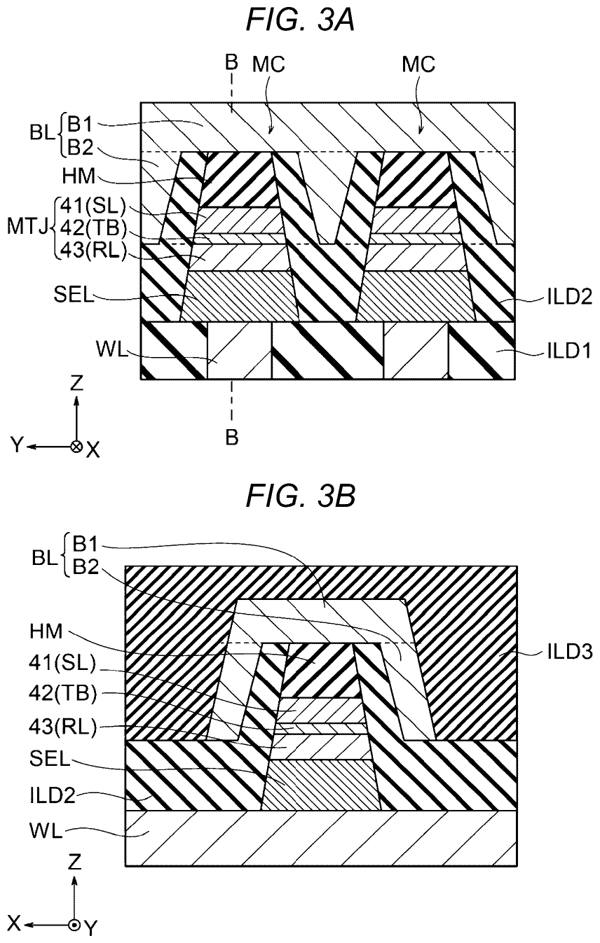

FIGS. 3A and 3B are cross-sectional views illustrating a configuration of the memory cell MC of the semiconductor memory device according to the first embodiment. FIG. 3A illustrates a cross-section in a direction along the bit line BL. FIG. 3B illustrates a cross-section in a direction along the word line WL. FIG. 3B is a cross-sectional view taken along a line B-B of FIG. 3A. The memory cell MC may be any of MCu or MCd. A positional relationship between the word line WL and the bit line BL may be swapped.

The memory cell MC is provided above (in a +Z direction of) a substrate (not illustrated). An extension direction of the word line WL is referred to as an X direction and an extension direction of the bit line BL is referred to as a Y direction. A direction perpendicular to the X-Y plane is referred to as a Z direction.

The plurality of word lines WL are provided above the substrate. The plurality of word lines WL extend in the X direction and are arranged in the Y direction. The plurality of memory cells MC are provided on the plurality of word lines WL. The plurality of memory cells MC are two-dimensionally arranged on the X-Y plane. The plurality of bit lines BL are provided on the plurality of memory cells MC. The plurality of bit lines BL extend in the Y direction and are arranged in the X direction.

The word lines WL and the bit lines BL have higher thermal conductivity than at least interlayer insulating films ILD1 to ILD3. For example, when the interlayer insulating films ILD1 to ILD3 are silicon oxide films or silicon nitride films, the word lines WL and the bit lines BL are configured with a conductive material having higher thermal conductivity than silicon oxide films or silicon nitride films. For the word lines WL and the bit lines BL, it is preferable to use, for example, a metal material having high thermal conductivity of 50 W/K·m or more. For example, the word lines WL and the bit lines BL are preferably configured with conductive metal such as Ag, Au, Cu, Al, W, Ni, or Ta.

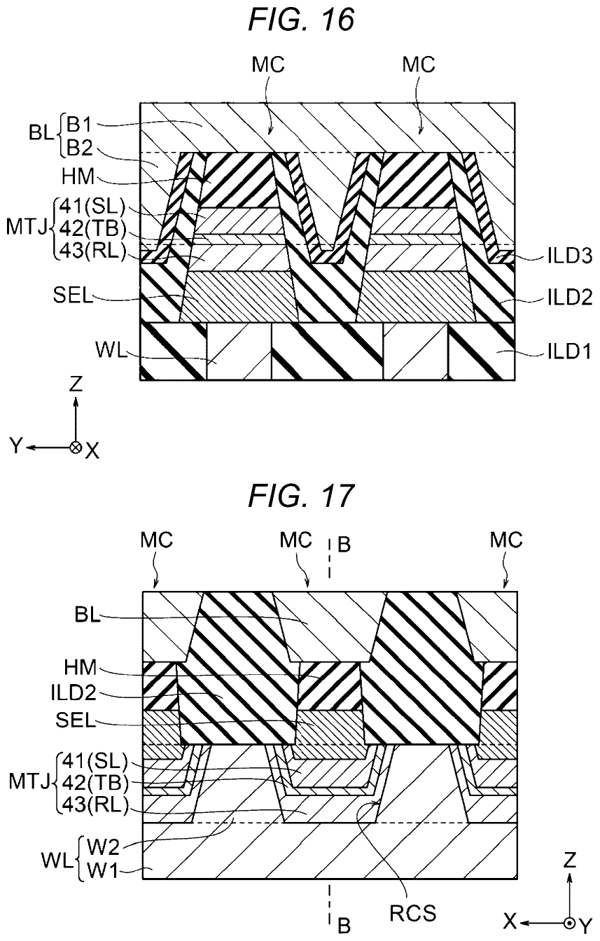

The interlayer insulating films ILD1 and ILD2 are provided between the plurality of word lines WL, between the plurality of memory cells MC, and between the plurality of bit lines BL. The interlayer insulating film ILD1 is an insulating film provided between the word lines WL adjacent to each other, and the interlayer insulating film ILD2 is an insulating film provided between the memory cells MC adjacent to each other. As will be described below with reference to FIG. 16, the interlayer insulating film ILD3 is provided between the bit lines BL adjacent to each other. The interlayer insulating films ILD1 to ILD3 are preferably configured with an insulating material having thermal conductivity of 20 W/K·m or more. The interlayer insulating films ILD1 to ILD3 are preferably configured with, for example, a silicon oxide film (SiO₂), a silicon nitride film (SiN), an aluminum nitride film (AlN), or an aluminum oxide film (Al₂O₃). The interlayer insulating film ILD2 is preferably configured with a material having higher thermal conductivity than a silicon oxide film. Accordingly, the interlayer insulating film ILD2 can radiate heat from the memory cells MC.

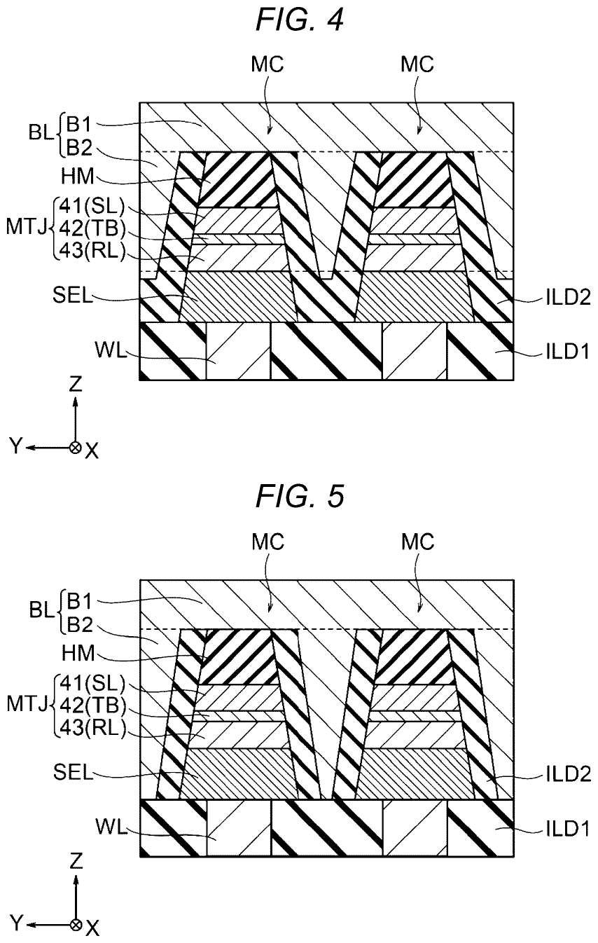

Each memory cell MC includes the magnetoresistive effect element MTJ and the selector SEL. A configuration of the magnetoresistive effect element MTJ will be described below with reference to FIG. 4.

The selector SEL includes two electrodes and a selector material provided between the two electrodes (none of which are illustrated). The two electrodes are configured with, for example, a conductive material such as titanium nitride (TiN) and tungsten nitride (WN). The selector material is an insulating material that contains an additive element. As the selector material, for example, silicon oxide containing silicon (Si) and oxygen (O) is used. When the selector material contains silicon oxide, the additive element of the selector material SEL is configured with arsenic (As), phosphorus (P), antimony (Sb), or boron (B).

The plurality of magnetoresistive effect elements MTJ are arranged in the X direction along the word lines WL and are arranged in the Y direction along the bit lines BL. Accordingly, the magnetoresistive effect elements MTJ are two-dimensionally arranged on the X-Y plane. One end of each magnetoresistive effect element MTJ is connected to the word line WL via at least one selector SEL. The other end of each magnetoresistive effect element MTJ is connected to the bit line BL.

The positional relationship between the magnetoresistive effect element MTJ and the selector SEL may be swapped in the Z direction.

A plurality of two-dimensional arrays of the memory cells MC illustrated in FIGS. 2, 3A, and 3B may be provided in the Z direction. Here, the two-dimensional array of two memory cells MC may be disposed with the bit line BL interposed therebetween and share the bit line BL. Accordingly, the plurality of memory cells MC can be three-dimensionally arranged. Here, the memory cell array 10 has a structure in which a pair of two word lines WLd and WLu correspond to one bit line BL, as illustrated in FIG. 2. The memory cell array 10 includes the memory cell MCd provided between the word line WLd and the bit line BL and the memory cell MCu provided between the bit line BL and the word line WLu. Of the two memory cells MC connected commonly to one bit line BL, the memory cell MC provided in an upper layer of the bit line BL is denoted by MCu in FIG. 2 and the memory cell MC provided in a lower layer of the bit line BL is denoted by MCd in FIG. 2. The memory cell MC according to the embodiment may be applied to any of MCu and MCd.

Here, in the embodiment, the bit line BL includes a wiring portion B1 and a protrusion portion B2. The wiring portion B1 extends in the Y direction above the plurality of memory cells MC and functions as a body of the bit line BL. The protrusion portion B2 protrudes in a −Z direction between the plurality of magnetoresistive effect elements MTJ adjacent to each other in the Y direction and is provided on a side wall of the magnetoresistive effect element MTJ via the interlayer insulating film ILD2. The wiring portion B1 is electrically connected to one end of the magnetoresistive effect element MTJ via a hard mask HM. The protrusion portion B2 is electrically separated from the side wall of the magnetoresistive effect element MTJ by the interlayer insulating film ILD2. The wiring portion B1 and the protrusion portion B2 are both configured with a same conductive material.

The magnetoresistive effect element MTJ is mainly configured such that a storage layer 41 configured with a ferromagnetic body, a tunnel barrier layer 42 configured with a non-magnetic body, and a reference layer 43 configured with a ferromagnetic body are stacked in the Z direction. The protrusion portion B2 protrudes to a depth of the tunnel barrier layer 42 from the wiring portion B1. That is, a lower end of the protrusion portion B2 reaches a depth (height) of the tunnel barrier layer 42 in the Z direction and is adjacent to the tunnel barrier layer 42 in the Y direction.

In a read operation or a write operation of data, the row selection circuit 11 and the column selection circuit 12 flow a current to the magnetoresistive effect element MTJ between the bit line BL and the word line WL. Here, the magnetoresistive effect element MTJ generates heat by the current. An insulating body such as a silicon oxide film and a silicon nitride film used for the interlayer insulating films ILD1 to ILD3 has relatively low thermal conductivity. Thus, when the bit line BL includes only the wiring portion B1 and does not include the protrusion portion B2, heat is accumulated in the magnetoresistive effect element MTJ and a temperature of the magnetoresistive effect element MTJ increases. An adverse influence may be given to reliability of the semiconductor memory device 1.

Meanwhile, in the embodiment, the protrusion portion B2 of the bit line BL protrudes to a depth of the tunnel barrier layer 42 from the wiring portion B1. Compared to the case where the bit line BL is configured with only the wiring portion B1, a distance from the bit line BL to the tunnel barrier layer 42 according to the embodiment is reduced due to the protrusion portion B2. The bit line BL is formed of conductive metal (for example, Ag, Au, Cu, Al, W, Ni, or Ta) having high thermal conductivity (for example, 50 W/K·m or more). Accordingly, heat generated in the magnetoresistive effect element MTJ is easily conducted to the protrusion portion B2 having high thermal conductivity via the relatively thin interlayer insulating film ILD2. The heat is radiated via the wiring portion B1. Accordingly, the heat of the magnetoresistive effect element MTJ is easily radiated, thereby improving reliability of the semiconductor memory device 1.

Since resistance of the tunnel barrier layer 42 is higher than the storage layer 41 and the reference layer 43 during a read or write operation, the tunnel barrier layer 42 particularly generates heat. Thus, the protrusion portion B2 preferably protrudes to a depth of the tunnel barrier layer 42 from the wiring portion B1. Accordingly, the protrusion portion B2 can efficiently radiate the heat generated in the tunnel barrier layer 42.

### First Modification of First Embodiment

FIG. 4 is a cross-sectional view illustrating a configuration of a memory cell MC of a semiconductor memory device according to a modification of the first embodiment. In the memory cell MC, the selector SEL is provided closer to the word line WL than the magnetoresistive effect element MTJ. In the modification, the protrusion portion B2 has a depth deeper than the magnetoresistive effect element MTJ and protrudes to a depth of the selector SEL from the wiring portion B1. That is, the lower end of the protrusion portion B2 reaches a depth (height) of an upper surface of the selector SEL and is adjacent to the selector SEL in the Y direction.

When the entire magnetoresistive effect element MTJ generates heat in the memory cell MC, the protrusion portion B2 preferably protrudes to the depth of the selector SEL from the wiring portion B1. Accordingly, the protrusion portion B2 can efficiently radiate the heat generated in the entire magnetoresistive effect element MTJ.

During a read or write operation, the selector SEL also generates heat. Thus, when the protrusion portion B2 protrudes to the depth of the selector SEL from the wiring portion B1, the protrusion portion B2 can also radiate the heat of the selector SEL.

### Second Modification of First Embodiment

FIG. 5 is a cross-sectional view illustrating a configuration of a memory cell MC of a semiconductor memory device according to another modification of the first embodiment. In the modification, the protrusion portion B2 has a deeper depth than the selector SEL from the wiring portion B1 and protrudes to a depth of the word line WL. That is, the lower end of the protrusion portion B2 reaches a depth (height) of the word line WL.

When the protrusion portion B2 protrudes to the depth of the word line WL from the wiring portion B1, the protrusion portion B2 can also radiate the heat of the selector SEL.

### Configuration Example of MTJ

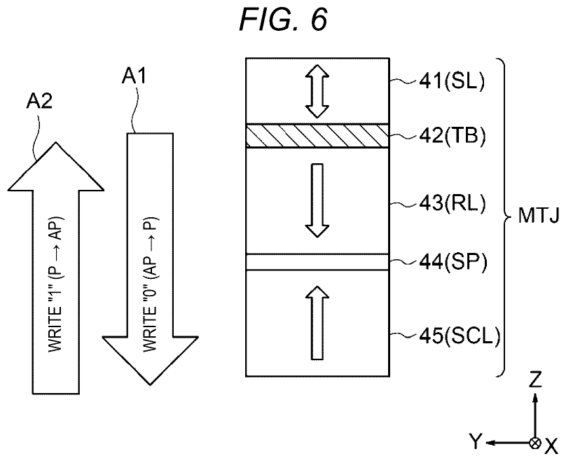

FIG. 6 is a cross-sectional view illustrating a configuration example of one magnetoresistive effect element MTJ. The magnetoresistive effect element MTJ includes a ferromagnetic body functioning as the storage layer 41 (a storage layer (SL)), a non-magnetic body functioning as the tunnel barrier layer 42 (a tunnel barrier (TB) layer), a ferromagnetic body functioning as the reference layer 43 (reference layer (RL)), a non-magnetic body functioning as a spacer layer 44 (a spacer layer (SL)) and a ferromagnetic body functioning as a shift canceling layer 45 (a shift canceling layer (SCL)). In FIG. 5, the spacer layer 44 and the shift canceling layer 45 are not illustrated.

In the magnetoresistive effect element MTJ, for example, from the word line WL to the bit line BL in a Z-axis direction, a plurality of bodies are stacked in the order of the storage layer 41, the tunnel barrier layer 42, the reference layer 43, the spacer layer 44, and the shift canceling layer 45. The stacking order of the layers may be reversed. The magnetoresistive effect element MTJ functions as, for example, a perpendicular magnetization type MTJ element in which a magnetization direction of a magnetic body is oriented in the stacking direction (±Z direction).

The storage layer 41 is ferromagnetic and has an axis direction of easy magnetization in the ±Z direction. The storage layer 41 has a magnetization direction oriented in either the bit line BL side or the word line WL side. The storage layer 41 may include, for example, cobalt iron boron (CoFeB) or iron boride (FeB) and can have a body-centered cubic crystal structure.

The tunnel barrier layer 42 is a non-magnetic insulating film and includes, for example, magnesium oxide (MgO). The tunnel barrier layer 42 is provided between the storage layer 41 and the reference layer 43 and configures a magnetic tunnel junction between the two ferromagnetic bodies.

The reference layer 43 is ferromagnetic and has an axis direction of easy magnetization in the Z direction. The reference layer 43 includes, for example, cobalt iron boron (CoFeB) or iron boride (FeB). A magnetization direction of the reference layer 43 is fixed and is oriented in the direction of the shift canceling layer 45 in the example of FIG. 6. The expression “the magnetization direction is fixed” means that the magnetization direction is not changed by a current having a magnitude that can reverse the magnetization direction of the storage layer 41 (spin torque).

The reference layer 43 may be a stacked body configured with a plurality of layers. For example, the reference layer 43 may have a stacked structure of ferromagnetic and non-magnetic conductors. The non-magnetic conductor of the reference layer 43 can include at least one metal selected from tantalum (Ta), hafnium (Hf), tungsten (W), zirconium (Zr), molybdenum (Mo), niobium (Nb), and titanium (Ti). The ferromagnetic body of the reference layer 43 can include at least one artificial lattice selected from a multilayer film of cobalt (Co) and platinum (Pt) (Co/Pt multilayer film), a multilayer film of cobalt (Co) and nickel (Ni) (Co/Ni multilayer film), and a multilayer film of cobalt (Co) and palladium (Pd) (Co/Pd multilayer film).

The spacer layer 44 is a non-magnetic conductive film and includes, for example, at least one element selected from ruthenium (Ru), osmium (Os), iridium (Ir), vanadium (V), and chromium (Cr).

The shift canceling layer 45 is ferromagnetic and has an axis direction of easy magnetization in the −Z direction. The shift canceling layer 45 includes at least one alloy selected from cobalt platinum (CoPt), cobalt nickel (CoNi), and cobalt palladium (CoPd). Similarly to the reference layer 43, the shift canceling layer 45 may also be a stacked body configured with a plurality of layers. Here, the shift canceling layer 45 may include at least one artificial lattice selected from a multilayer film of cobalt (Co) and platinum (Pt) (Co/Pt multilayer film), a multilayer film of cobalt (Co) and nickel (Ni) (Co/Ni multilayer film), and a multilayer film of cobalt (Co) and palladium (Pd) (Co/Pd multilayer film).

A magnetization direction of the shift canceling layer 45 is fixed and is oriented in the direction of the reference layer 43 in the example of FIG. 6.

The reference layer 43 and the shift canceling layer 45 are synthesized to have magnetization directions antiparallel to each other. Such synthesized structure of the reference layer 43, the spacer layer 44, and the shift canceling layer 45 is referred to as a synthetic anti-ferromagnetic (SAF) structure. Accordingly, the shift canceling layer 45 can cancel an effect of a leakage magnetic field of the reference layer 43 on the magnetization direction of the storage layer 41. As a result, in the storage layer 41, asymmetry in magnetization reversal difficulty is reduced. That is, difference in magnetization direction reversal difficulty of reversal from one side to the other side and reversal from the other side to the one side is reduced.

In the first embodiment, a spin injection writing method of flowing a write current directly to the magnetoresistive effect element MTJ, injecting a spin torque to the storage layer 41 and the reference layer 43 by the write current, and controlling the magnetization direction of the storage layer 41 and the magnetization direction of the reference layer 43 is adopted. The magnetoresistive effect element MTJ can enter one of a low resistance state and a high resistance state depending on whether a relative relationship between the magnetization directions of the storage layer 41 and the reference layer 43 is parallel or anti-parallel.

When a write current Iw0 flows to the magnetoresistive effect element MTJ in a direction of an arrow A1, that is, a direction from the storage layer 41 to the reference layer 43, the relative relationship between the magnetization directions of the storage layer 41 and the reference layer 43 becomes parallel. In the case of parallel, a resistance value of the magnetoresistive effect element MTJ becomes relatively low, and the magnetoresistive effect element MTJ is set to a low resistance state. The low resistance state is referred to as a parallel (P) state and is defined as, for example, a data 0 state.

When a write current Iw1 greater than the write current Iw0 flows to the magnetoresistive effect element MTJ in a direction of an arrow A2 opposite to the arrow A1, the relative relationship between the magnetization directions of the storage layer 41 and the reference layer 43 becomes anti-parallel. In the case of anti-parallel, the resistance value of the magnetoresistive effect element MTJ becomes relatively high, and the magnetoresistive effect element MTJ is set to a high resistance state. The high resistance state is referred to as an anti-parallel (AP) state and is defined as, for example, a data 1 state. The P state may be defined as data 1 and the AP state may be defined as data 0.

### Manufacturing Method in First Embodiment

Next, a method of manufacturing the semiconductor memory device 1 according to the first embodiment will be described.

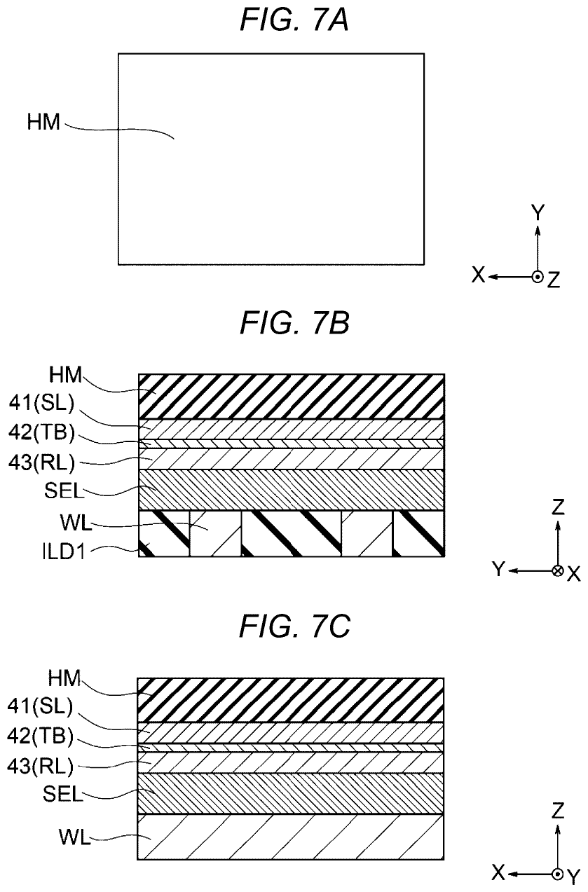

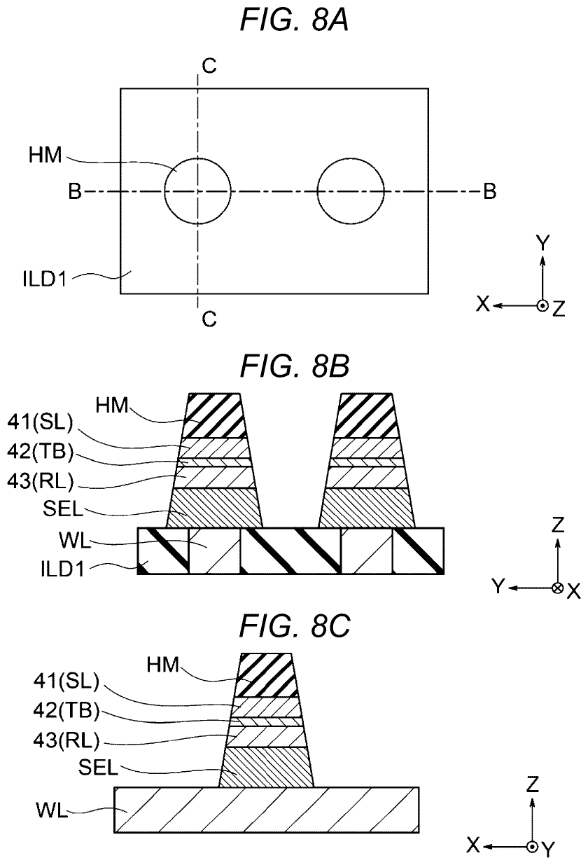

FIGS. 7A to 15C are diagrams illustrating an example of the method of manufacturing the semiconductor memory device 1 according to the first embodiment. FIGS. 7A, 8A, 9A, . . . , and 15A are plan views when viewed in the Z direction. FIGS. 7B, 8B, 9B, . . . , and 15B are cross-sectional views in the Y direction (extension direction of the bit line BL). FIGS. 7C, 8C, 9C, . . . , and 15C are cross-sectional views in the X direction (extension direction of the word line WL). FIG. 8B corresponds to a cross-section taken along a line B-B of FIG. 8A. FIG. 8C corresponds to a cross-section taken along a line C-C of FIG. 8A.

First, the plurality of word lines WL are formed above the substrate (not illustrated). As illustrated in FIG. 7B, the word line WL is formed to be buried in the interlayer insulating film ILD1. The surface of the word line WL is exposed.

Subsequently, a material of the selector SEL is deposited on the interlayer insulating film ILD1 and the word line WL. The material of the selector SEL is, for example, stacked materials of an electrode material, a selector material, and an electrode material. The electrode material, the selector material, and the electrode material are stacked on the interlayer insulating film ILD1 and the word line WL. In the drawings, the stacked materials of the selector SEL are displayed as one film for convenience.

Subsequently, a material of the magnetoresistive effect element MTJ is stacked on the material of the selector SEL. For example, as illustrated in FIGS. 7B and 7C, the material of the magnetoresistive effect element MTJ is stacked materials of the reference layer 43, the tunnel barrier layer 42, and the storage layer 41. Materials of the reference layer 43, the tunnel barrier layer 42, and the storage layer 41 are deposited in this order on the stacked materials of the selector SEL. Although not illustrated in FIGS. 7B and 7C, the spacer layer 44 and the shift canceling layer 45 in FIG. 6 may be stacked on the material of the selector SEL before the reference layer 43.

Subsequently, a material of the hard mask HM is deposited on the material of the magnetoresistive effect element MTJ. In the hard mask HM, for example, conductive metal such as Ta, TaN, Ru, Pt, Ti, or TiN or nitride thereof is used. Accordingly, the structure illustrated in FIGS. 7A to 7C is obtained.

Subsequently, the hard mask HM is processed in a layout pattern of the magnetoresistive effect element MTJ by a lithographic technology and an etching technology. Subsequently, as illustrated in FIGS. 8A to 8C, the stacked materials of the magnetoresistive effect element MTJ and the selector SEL are processed (e.g., patterned) using the hard mask HM as a mask. Accordingly, the magnetoresistive effect element MTJ and the selector SEL are formed as the memory cell MC arranged on the X-Y plane. The side walls of the magnetoresistive effect element MTJ and the selector SEL have a forward taper shape by an etching process. That is, each of the magnetoresistive effect element MTJ and the selector SEL has a tapered side surface such that a width in the X or Y direction is narrowed along the-Z direction from the bit line BL to the word line WL.

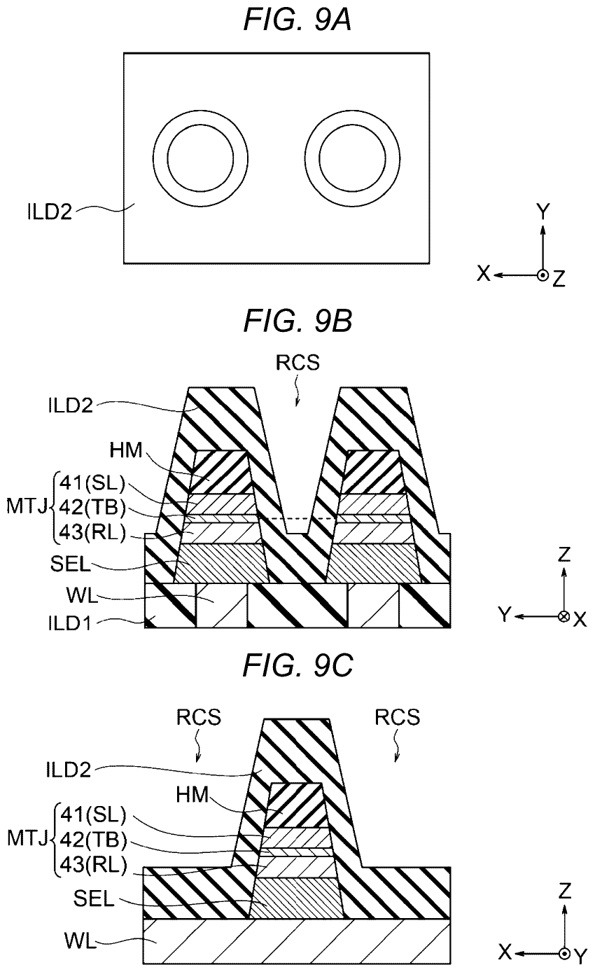

Subsequently, as illustrated in FIGS. 9A to 9C, a material of the interlayer insulating film ILD2 is deposited on the side walls of the magnetoresistive effect element MTJ and the selector SEL, the hard mask HM, and the interlayer insulating film ILD1. A space between the magnetoresistive effect elements MTJ adjacent to each other is not completely buried by the material of the interlayer insulating film ILD2, and a recess RCS remains to the depth of the tunnel barrier layer 42.

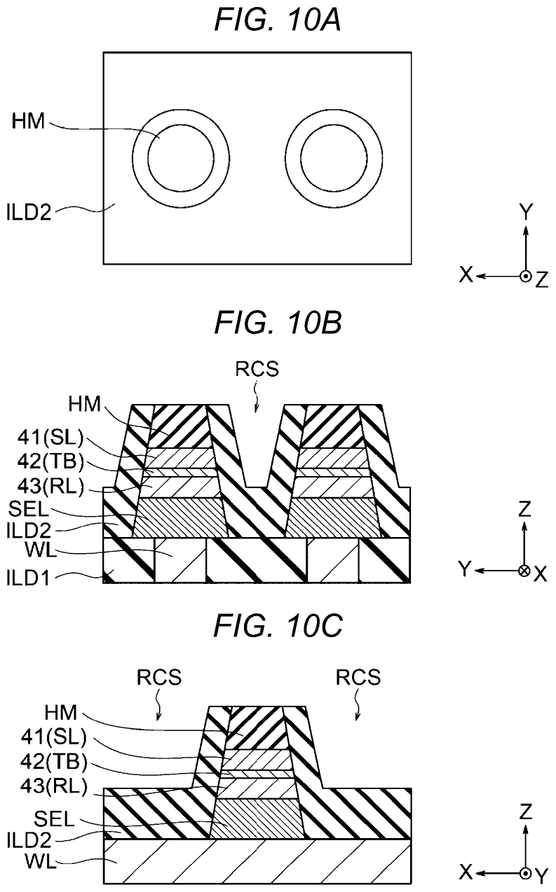

Subsequently, as illustrated in FIGS. 10A to 10C, the materials of the interlayer insulating films ILD are etched back by a chemical mechanical polishing (CMP) method or the like to expose the surface of the hard mask HM. The recess RCS can be filled by a sacrificial layer before etched back step and removed by selective etching after etched back. Here, the recess RCS remains between the magnetoresistive effect elements MTJ adjacent to each other.

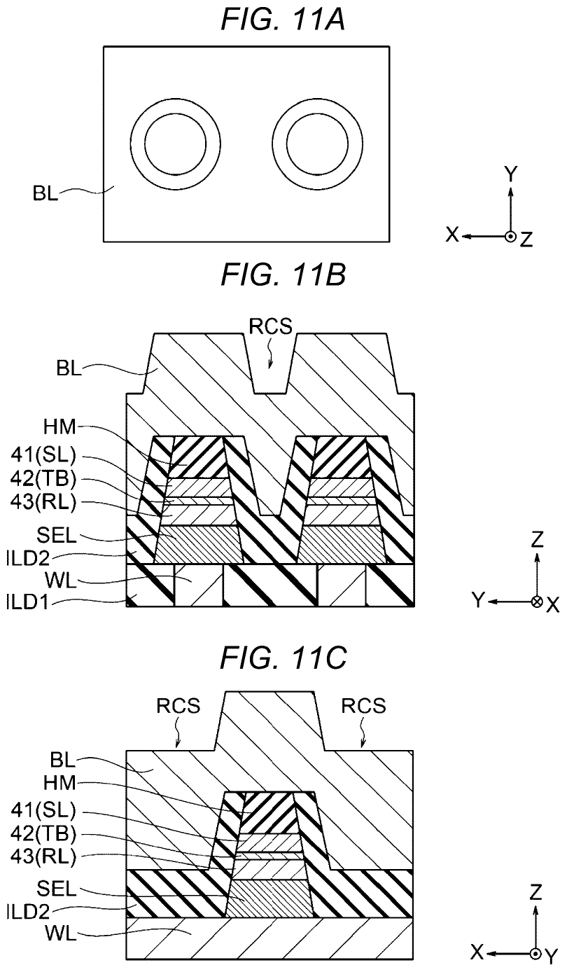

Subsequently, as illustrated in FIGS. 11A to 11C, a material of the bit line BL is deposited on the interlayer insulating films ILD and the hard mask HM. Here, the material of the bit line BL is buried in the recess RCS between the magnetoresistive effect elements MTJ adjacent to each other.

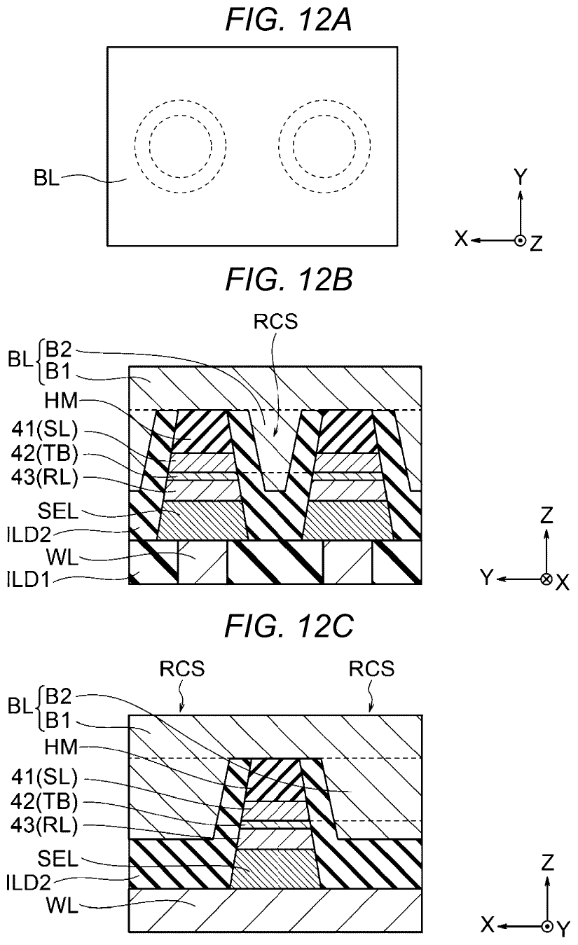

Subsequently, as illustrated in FIGS. 12A to 12C, the material of the bit line BL is etched back by a CMP method or the like to flatten the surface of the material of the bit line BL.

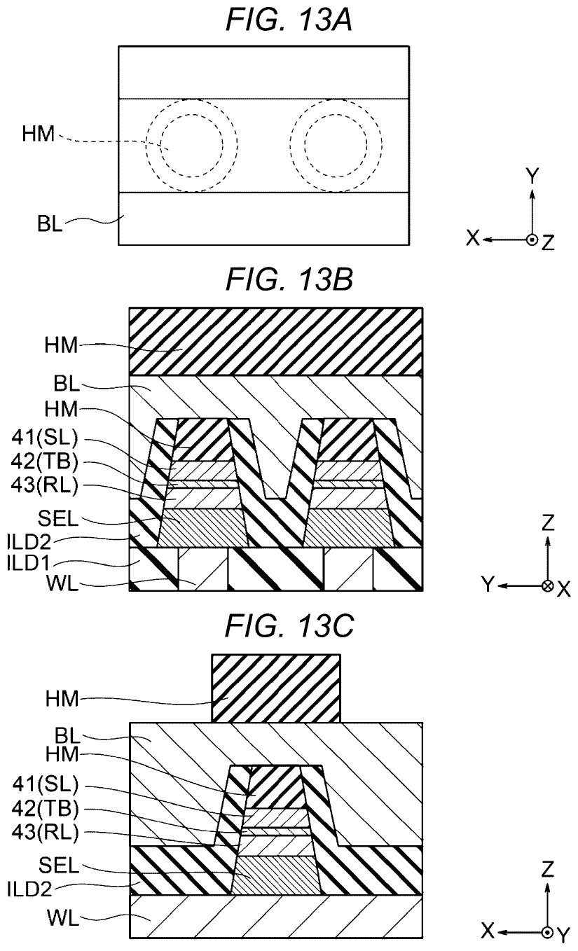

Subsequently, as illustrated in FIGS. 13A to 13C, the material of the hard mask HM is deposited again on the material of the bit line BL. The material of the hard mask HM is processed in a layout of the bit line BL by a lithographic technology and an etching technology.

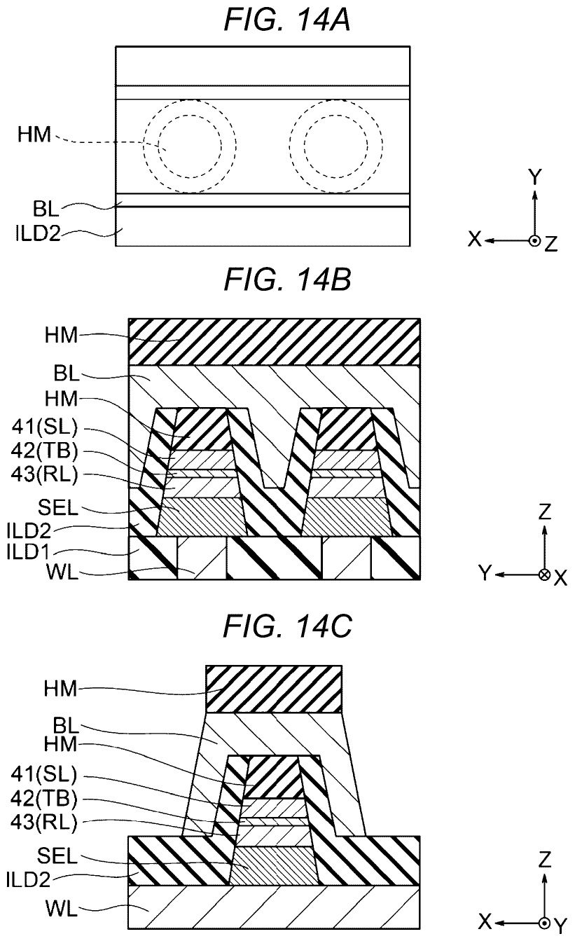

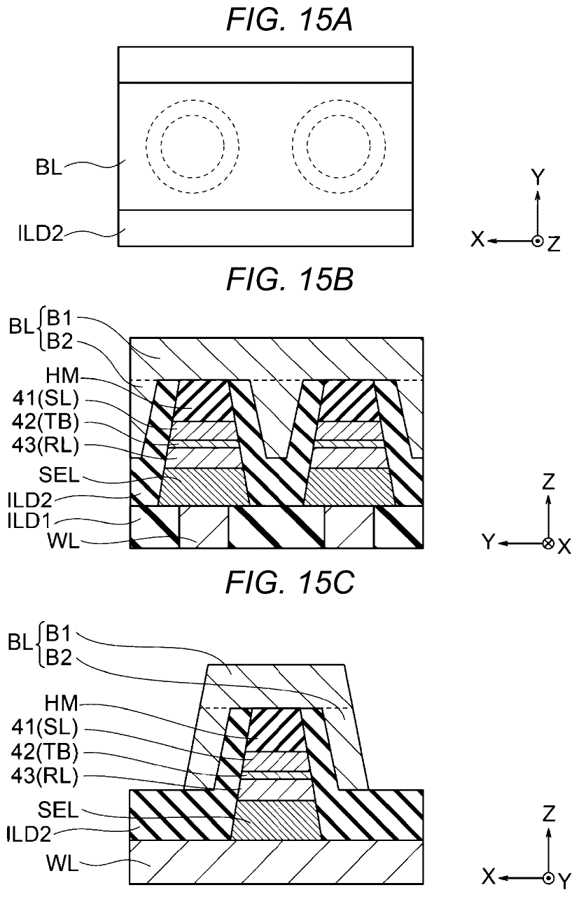

Subsequently, as illustrated in FIGS. 14A to 14C, the material of the bit line BL is processed using the hard mask HM on the bit line BL. Accordingly, the bit line BL is formed. When the hard mask HM on the bit line BL is removed, the structure illustrated in FIGS. 15A to 15C is obtained.

A portion of the bit line BL left on the hard mask HM becomes the wiring portion B1. A portion of the bit line BL buried in the recess RCS becomes the protrusion portion B2. The protrusion portion B2 is buried to the depth of the tunnel barrier layer 42 between the magnetoresistive effect elements MTJ adjacent to each other. Thus, the bit line BL is provided on the side walls of the magnetoresistive effect element MTJ via the interlayer insulating film ILD2. Accordingly, heat in the tunnel barrier layer 42 is easily radiated to the bit line BL via the protrusion portion B2.

Thereafter, by forming the interlayer insulating film, the multilayer writing layer, and the like (not illustrated) on the bit line BL, the semiconductor memory device 1 according to the first embodiment is completed.

In the modifications of the first embodiment, by adjusting the thickness of the interlayer insulating film ILD2, it is possible to deepen the depth of the recess RCS. A manufacturing method according to the modifications and the like may be similar to the manufacturing method according to the first embodiment.

### Second Embodiment

FIG. 16 is a cross-sectional view illustrating a configuration of a memory cell MC of a semiconductor memory device according to a second embodiment. In the second embodiment, the interlayer insulating film ILD3 is provided between the protrusion portion B2 and the interlayer insulating film ILD2. The interlayer insulating film ILD3 is configured with, for example, a silicon oxide film (SiO₂), a silicon nitride film (SiN), an aluminum nitride film (AlN), or an aluminum oxide film (Al₂O₃). When the interlayer insulating film ILD2 is configured with, for example, a silicon oxide film, the interlayer insulating film ILD3 is preferably configured with an insulating material having higher thermal conductivity than the silicon oxide film. Accordingly, heat in the tunnel barrier layer 42 is easily radiated to the bit line BL via the interlayer insulating film ILD3.

By stacking two layers of the interlayer insulating films ILD2 and ILD3 on the side wall of the magnetoresistive effect element MTJ, electrical separation between the protrusion portion B2 and the side wall of the magnetoresistive effect element MTJ is ensured.

Other configurations of the second embodiment may be the same as the configurations of the first embodiment. Thus, in the second embodiment, it is possible to obtain similar advantages as those of the first embodiment. The second embodiment can also be applied to the first and second modifications of the first embodiment.

The material of the interlayer insulating film ILD3 is stacked on the material of the interlayer insulating film ILD2 after the material of the interlayer insulating film ILD2 is deposited. The interlayer insulating film ILD2 is processed after the processing of the interlayer insulating film ILD3. Forming processes of the second embodiment and the like may be similar to the forming processes of the first embodiment.

### Third Embodiment

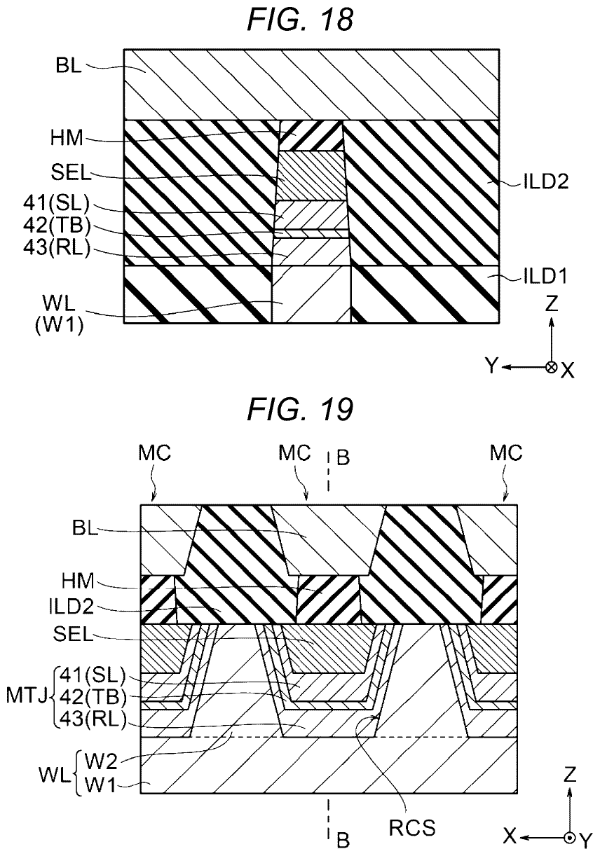

FIGS. 17 and 18 are cross-sectional views illustrating a configuration of a memory cell MC of a semiconductor memory device according to a third embodiment. FIG. 17 illustrates a cross-section in a direction along the word line WL. FIG. 18 illustrates a cross-section in a direction along the bit line BL. FIG. 18 is a cross-sectional view taken along a line B-B of FIG. 17.

In the third embodiment, the word lines WL are provided between the plurality of magnetoresistive effect elements MTJ adjacent to each other in the X direction. The word line WL includes a wiring portion W1 and a protrusion portion W2. The wiring portion W1 extends in the X direction below the plurality of memory cells MC and functions as a body of the word line WL. The protrusion portion W2 protrudes in the +Z direction between the plurality of magnetoresistive effect elements MTJ adjacent to each other in the X direction and is provided on a bottom surface and a side surface of the reference layer 43 of the magnetoresistive effect element MTJ. The wiring portion W1 is electrically connected to the other end of the magnetoresistive effect element MTJ. However, the wiring portion W1 is electrically separated from the end surfaces of the tunnel barrier layer 42 and the storage layer 41 of the magnetoresistive effect element MTJ. The protrusion portion W2 is electrically separated from the tunnel barrier layer 42 and the storage layer 41 of the magnetoresistive effect element MTJ by the interlayer insulating film ILD2. The wiring portion W1 and the protrusion portion W2 are both configured with a same conductive material.

The protrusion portion W2 extends to a height of the tunnel barrier layer 42 from the wiring portion W1. That is, an upper end of the protrusion portion W2 reaches a height of the tunnel barrier layer 42 in the Z direction and is adjacent to the tunnel barrier layer 42 in the X direction.

Accordingly, in the third embodiment, the protrusion portion W2 of the word line WL protrudes to a height of the tunnel barrier layer 42 from the wiring portion W1. Compared to the word line WL including only the wiring portion W1, in the word line WL according to the third embodiment, a distance to the tunnel barrier layer 42 is reduced due to the protrusion portion W2. The word line WL is formed of conductive metal (for example, Ag, Au, Cu, Al, W, Ni, or Ta) having high thermal conductivity (for example, 50 W/K·m or more). Accordingly, heat generated in the magnetoresistive effect element MTJ is easily transmitted to the protrusion portion W2 having high thermal conductivity via the reference layer 43 or the interlayer insulating film ILD2. The heat is radiated via the wiring portion W1. Accordingly, heat of the magnetoresistive effect element MTJ is easily radiated, thereby improving reliability of the semiconductor memory device 1.

The protrusion portion W2 preferably protrudes to a height of the tunnel barrier layer 42 from the wiring portion W1. Accordingly, the protrusion portion W2 can efficiently radiate heat generated in the tunnel barrier layer 42.

In the memory cell MC, the selector SEL is provided closer to the bit line BL than the magnetoresistive effect element MTJ. Here, the protrusion portion W2 protrudes to a height of the selector SEL from the wiring portion W1. Here, since the protrusion portion W2 protrudes to the height of the selector SEL from the wiring portion W1, the protrusion portion W2 can efficiently radiate heat of the selector SEL.

The magnetoresistive effect element MTJ is provided in the recess RCS formed in the word line WL. Accordingly, the storage layer 41, the tunnel barrier layer 42, and the reference layer 43 of the magnetoresistive effect element MTJ is bent in the +Z direction while being stacked along the side surface of the protrusion portion W2.

The selector SEL and the hard mask HM are provided on the magnetoresistive effect element MTJ. The bit line BL is provided on the hard mask HM.

The interlayer insulating film ILD2 is provided between the selectors SEL adjacent to each other in the X direction, between the hard masks HM adjacent to each other in the X direction, and between the bit lines BL adjacent to each other in the X direction. The interlayer insulating film ILD2 is provided on the protrusion portion W2 of the word line WL and the magnetoresistive effect element MTJ.

The cross-section of the semiconductor memory device 1 in the Y direction illustrated in FIG. 18 differs from the cross-section in the Y direction in the first embodiment in that the protrusion portion B2 is not provided in the bit line BL. However, the rest of the cross-section in the Y direction in the third embodiment may be the same as the cross-section in the Y direction in the first embodiment.

In the third embodiment, the protrusion portion W2 of the word line WL protrudes to a height of the tunnel barrier layer 42 from the wiring portion W1. Accordingly, compared to the word line WL where the protrusion portion W2 is not provided, in the word line WL, a distance to the tunnel barrier layer 42 is reduced due to the protrusion portion W2. Since the word line WL is configured with a material having high thermal conductivity, heat generated in the magnetoresistive effect element MTJ is easily transmitted to the protrusion portion W2 having high thermal conductivity via the reference layer 43 or the interlayer insulating film ILD2 that are relatively thin. The heat is radiated via the wiring portion W1. Accordingly, heat of the magnetoresistive effect element MTJ is efficiently radiated, thereby improving reliability of the semiconductor memory device 1.

### First Modification of Third Embodiment

FIG. 19 is a cross-sectional view illustrating a configuration of a memory cell MC of a semiconductor memory device according to a modification of the third embodiment. In the memory cell MC, the selector SEL is provided closer to the bit line BL than the magnetoresistive effect element MTJ. In the modification, the protrusion portion W2 protrudes to a height of the selector SEL from the wiring portion W1. That is, the upper end of the protrusion portion W2 reaches a depth (height) of the upper surface of the selector SEL and is adjacent to the selector SEL in the X direction.

When the entire magnetoresistive effect element MTJ generates heat in the memory cell MC, the protrusion portion W2 preferably protrudes to the depth of the selector SEL from the wiring portion W1. Accordingly, the protrusion portion W2 can efficiently radiate heat generated in the entire magnetoresistive effect element MTJ.

During a read or write operation, the selector SEL also generates heat. Thus, when the protrusion portion W2 protrudes to the depth of the selector SEL from the wiring portion W1, the protrusion portion W2 can also radiate heat of the selector SEL.

In the third embodiment, the positional relationship between the magnetoresistive effect element MTJ and the selector SEL may be opposite.

### Manufacturing Method in Third Embodiment

Next, a method of manufacturing the semiconductor memory device 1 according to the third embodiment will be described.

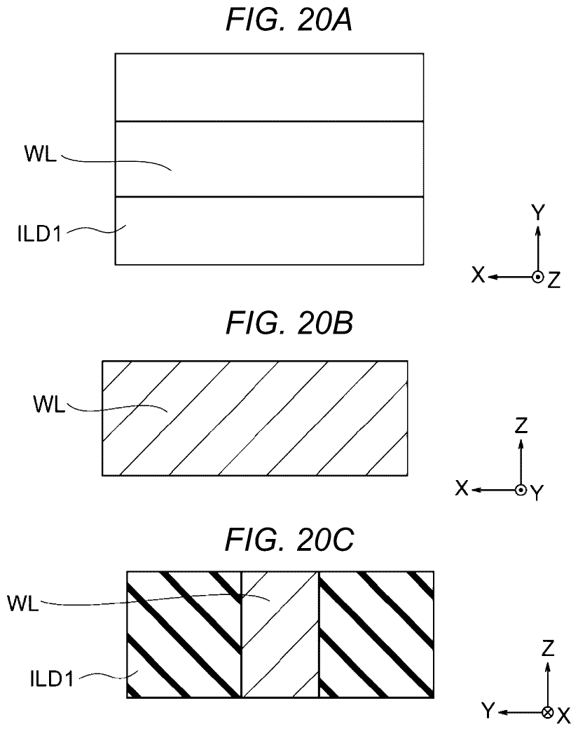

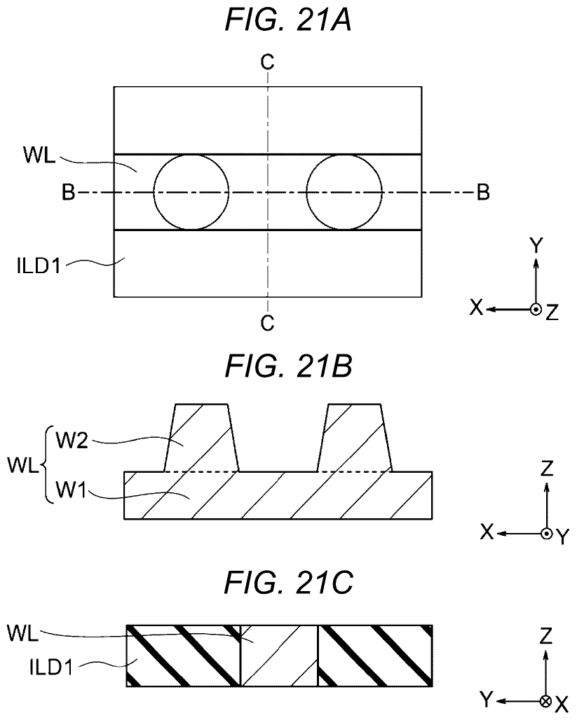

FIGS. 20A to 29C are diagrams illustrating an example of the method of manufacturing the semiconductor memory device 1 according to the third embodiment. FIGS. 20A, 21A, 22A, . . . , and 29A are plan views when viewed in the Z direction. FIGS. 20B, 21B, 22B, . . . , and 29B are cross-sectional views in the Y direction (extension direction of the bit line BL). FIGS. 20C, 21C, 22C, . . . , and 29C are cross-sectional views in the X direction (extension direction of the word line WL). FIG. 21B corresponds to a cross-section taken along a line B-B of FIG. 21A. FIG. 21C corresponds to a cross-section taken along a line C-C of FIG. 21A.

First, the plurality of word lines WL are formed above the substrate (not illustrated). As illustrated in FIGS. 20A and 20C, the word line WL is formed to be buried in the interlayer insulating film ILD1. The surface of the word line WL is exposed.

Subsequently, the word line WL is processed by a lithographic technology and an etching technology, and as illustrated in FIGS. 21A and 21B, the wiring portion W1 and the protrusion portion W2 are formed. The protrusion portion W2 protrudes in the +Z direction from the surface of the wiring portion W1. As illustrated in FIG. 21C, the interlayer insulating film ILD1 is etched to the same height level as the surface of the wiring portion W1.

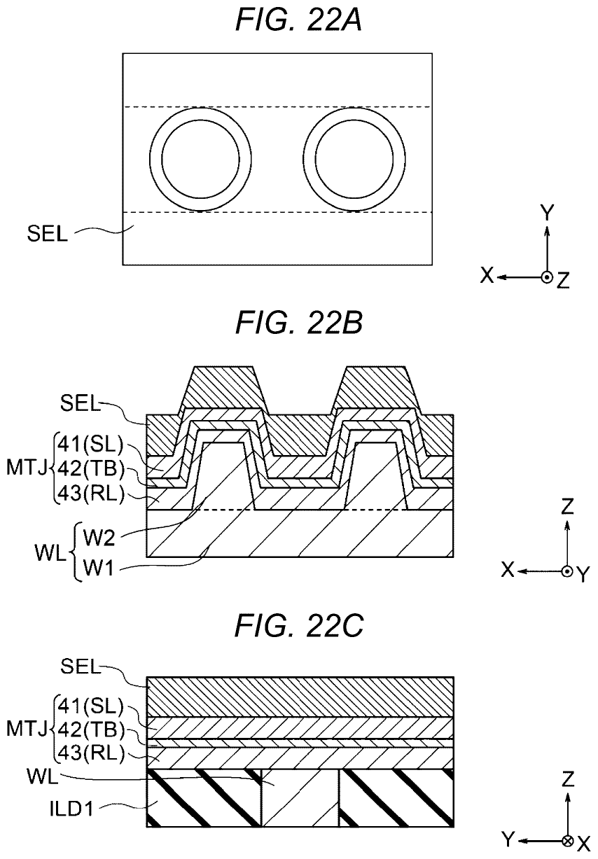

Subsequently, as illustrated in FIGS. 22A and 22B, the material of the magnetoresistive effect element MTJ is stacked on the word line WL and the interlayer insulating film ILD1. The materials of the reference layer 43, the tunnel barrier layer 42, and the storage layer 41 are stacked in this order on the stacked material of the selector SEL. Although not illustrated in FIGS. 22B and 22C, the spacer layer 44 and the shift canceling layer 45 in FIG. 6 may be stacked on the material of the selector SEL before the reference layer 43.

Subsequently, the material of the selector SEL is deposited on the material of the magnetoresistive effect element MTJ. The material of the selector SEL is, for example, stacked materials of an electrode material, a selector material, and an electrode material. The electrode material, the selector material, and the electrode material are stacked on the material of the magnetoresistive effect element MTJ. In the drawings, the stacked materials of the selector SEL are displayed as one film for convenience. Accordingly, the structure illustrated in FIGS. 22A to 22C is obtained.

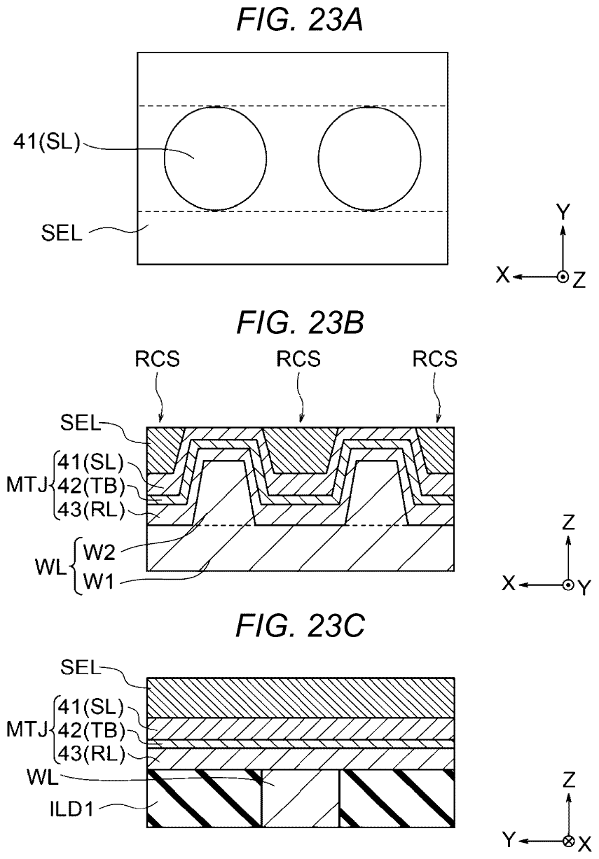

Subsequently, as illustrated in FIGS. 23A to 23C, the material of the selector SEL is etched back by a CMP method or the like to expose the surface of the storage layer 41. Here, the materials of the magnetoresistive effect element MTJ and the selector SEL remain in the recess RCS between the protrusion portions W2 adjacent to each other in the X direction.

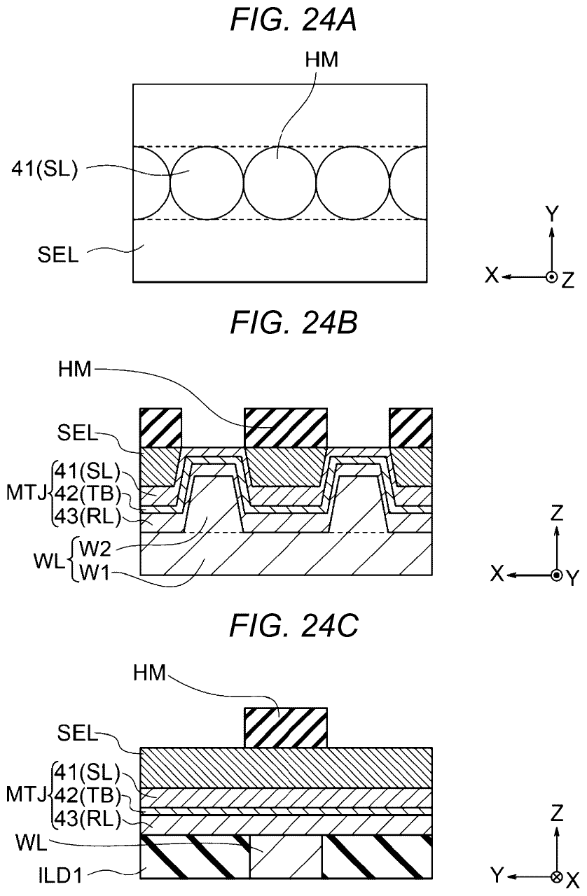

Subsequently, as illustrated in FIGS. 24A to 24C, the material of the hard mask HM is deposited on the material of the selector SEL. The material of the hard mask HM is processed in a layout of the magnetoresistive effect element MTJ by a lithographic technology and an etching technology.

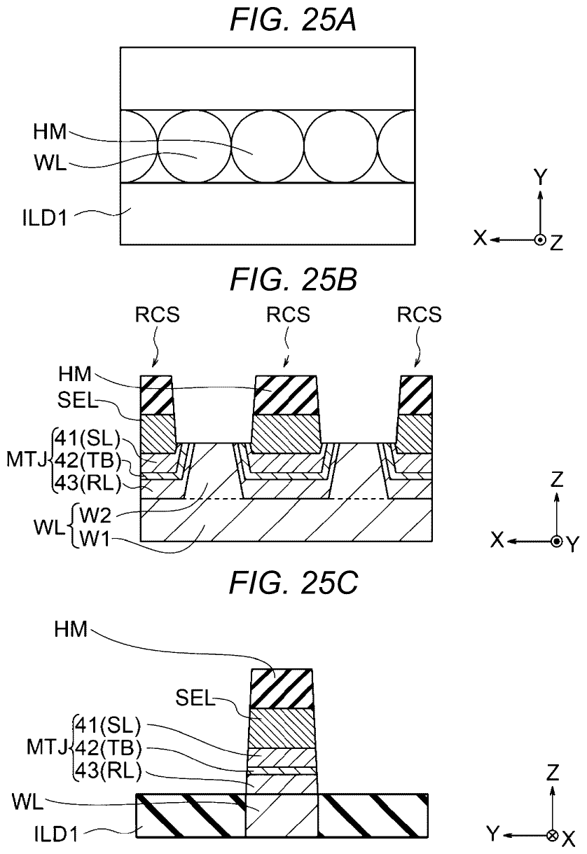

Subsequently, as illustrated in FIGS. 25A to 25C, the stacked materials of the selector SEL and the magnetoresistive effect element MTJ are processed using the hard mask HM as a mask. Here, for example, by emitting ions in a diagonal direction along the Z-axis that is along an X-axis by an ion beam etching (IBE) method, a shadowing effect caused by the hard mask HM is obtained. Thus, the selector SEL and the magnetoresistive effect element MTJ of a portion where the word line WL does not exist below can be removed while the protrusion portion W2 remains between the magnetoresistive effect elements MTJ. Accordingly, the magnetoresistive effect element MTJ and the selector SEL are formed as the memory cell MC arranged on the X-Y plane.

Here, as illustrated in FIG. 25B, the material of the magnetoresistive effect element MTJ above the protrusion portion W2 is removed, and the magnetoresistive effect element MTJ is separated in the X direction for each memory cell MC. The magnetoresistive effect element MTJ is buried in the recess RCS between the protrusion portions W2 adjacent to each other in the X direction, thereby forming the selector SEL on the magnetoresistive effect element MTJ. The protrusion portion W2 is provided to a position higher than the tunnel barrier layer 42 from the surface of the wiring portion W1, thereby reaching a height of the lower surface of the selector SEL.

As illustrated in FIG. 25C, the material of the magnetoresistive effect element MTJ on the interlayer insulating film ILD1 is removed, and the magnetoresistive effect element MTJ is separated in the Y direction for each memory cell MC. On the cross-section in the Y direction illustrated in FIG. 25C, the side walls of the selector SEL and the magnetoresistive effect element MTJ have a forward taper shape by an etching process. That is, each of the selector SEL and the magnetoresistive effect element MTJ has a tapered side surface such that a width in the Y direction is narrowed along the −Z direction from the bit line BL to the word line WL.

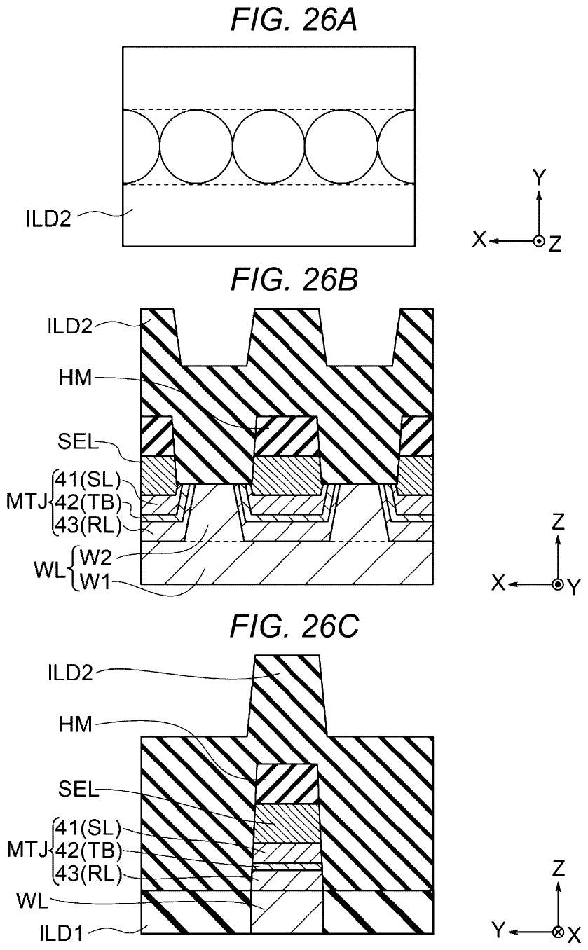

Subsequently, as illustrated in FIGS. 26A to 26C, the material of the interlayer insulating film ILD2 is deposited on the side walls of the magnetoresistive effect element MTJ and the selector SEL, the hard mask HM, the protrusion portion W2, and the interlayer insulating film ILD1. The material of the interlayer insulating film ILD2 is deposited to bury a space between the magnetoresistive effect elements MTJ adjacent to each other.

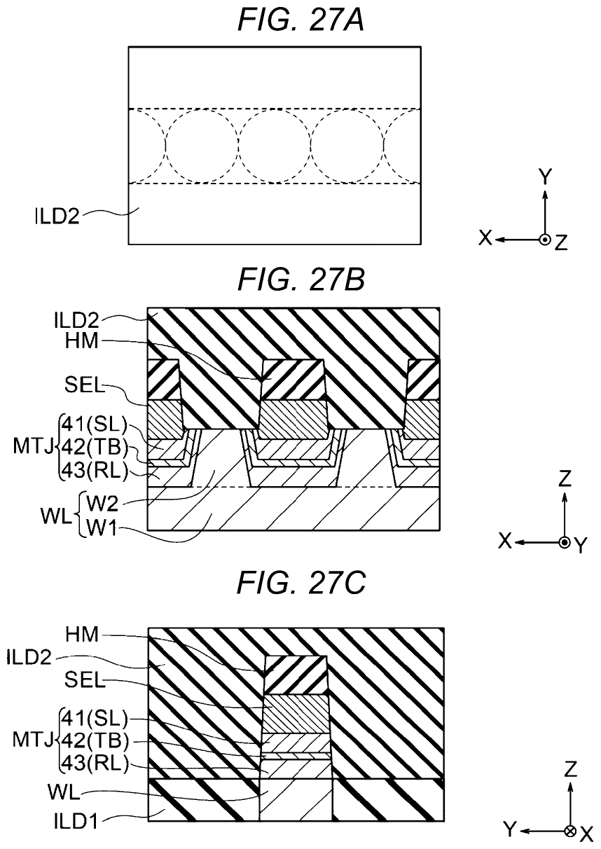

Subsequently, as illustrated in FIGS. 27A to 27C, the material of the interlayer insulating film ILD2 is flattened by a CMP method or the like.

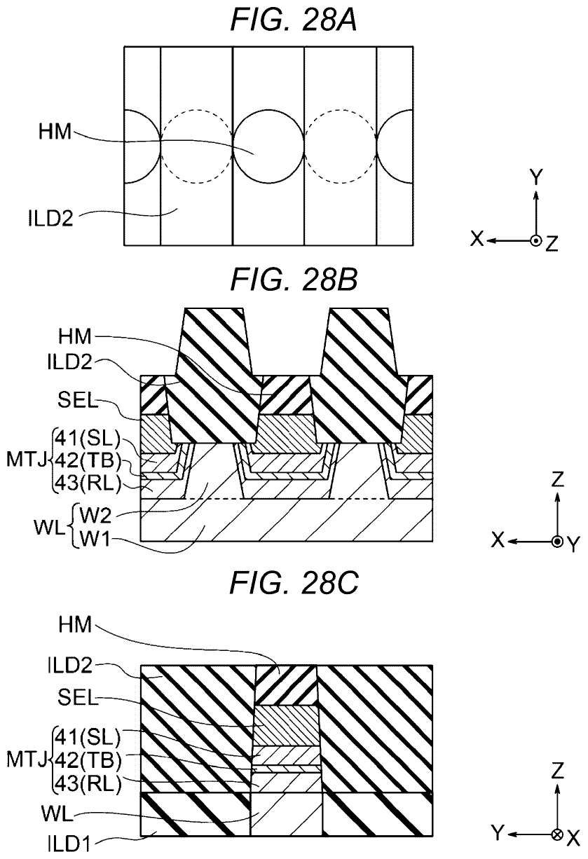

Next, as illustrated in FIGS. 28A to 28C, the interlayer insulating film ILD2 in a portion where the bit line BL is formed is removed by a lithographic technology and an etching technology. Accordingly, a groove extending in the Y direction is formed in the portion where the bit line BL is formed.

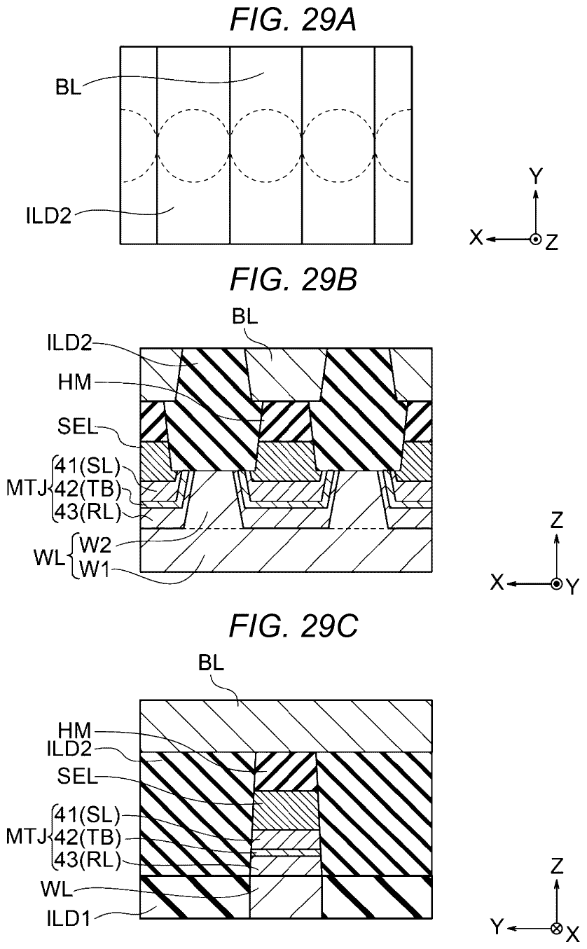

Subsequently, as illustrated in FIGS. 29A to 29C, the material of the bit line BL is deposited on the interlayer insulating film ILD2. Then, the material of the bit line BL is etched back until the surface of the interlayer insulating film ILD2 is exposed by using the CMP method or the like. Accordingly, the material of the bit line BL is buried in the groove formed in the interlayer insulating film ILD2. Thus, the bit line BL is formed.

Thereafter, an interlayer insulating film and a multi-wiring layer (none of which are not illustrated) are formed, and the semiconductor memory device 1 according to the third embodiment is completed.

A modification of the third embodiment can be realized by adjusting the height of the protrusion portion W2 of the word line WL, the thickness of the material of the magnetoresistive effect element MTJ, or the thickness of the material of the selector SEL. A manufacturing method according to the modification of the third embodiment or the like may be similar to the manufacturing method according to the third embodiment.

The first and third embodiments may be combined. That is, in the semiconductor memory device 1, the bit line BL may include the protrusion portion B2 and the word line WL may include the protrusion portion W2. The protrusion portions B2 and W2 are electrically separated from each other. By providing both the protrusion portions B2 and W2, the semiconductor memory device 1 can radiate heat generated in the magnetoresistive effect element MTJ and the selector SEL further efficiently.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a plurality of first wirings extending in a first direction;
a plurality of second wirings extending in a second direction intersecting the first direction;
a plurality of memory cells provided between the plurality of first wirings and the plurality of second wirings and arranged in the first or second direction, each of the memory cells including a corresponding one of a plurality of variable resistance elements and a corresponding one of a plurality of selectors, the selectors each configured to switch a current flowing to the corresponding variable resistance element; and
a first insulating film provided between the plurality of memory cells, wherein
the first wirings are each provided between adjacent ones of the variable resistance elements in the first direction, or
the second wirings are each provided between adjacent ones of the plurality of variable resistance elements arranged in the second direction.

2. The semiconductor memory device according to claim 1, wherein the first wirings each include a first wiring portion extending above the plurality of memory cells and a first protrusion portion protruding from the first wiring portion in a third direction that intersects the first and second directions, and wherein the first protrusion portion is interposed between the adjacent variable resistance elements arranged in the first direction.

3. The semiconductor memory device according to claim 2, wherein
the variable resistance element includes a storage layer configured with a ferromagnetic body, a barrier layer configured with a non-magnetic body, and a reference layer configured with a ferromagnetic body, wherein the storage layer, the barrier layer, and the reference layer are stacked in the third direction, and wherein the first protrusion portion protrudes with a depth from the first wiring portion to align the barrier layer.

4. The semiconductor memory device according to claim 2, wherein
the selector of each memory cell is provided closer to the second wirings than the corresponding variable resistance element, and
the first protrusion portion protrudes with a depth from the first wiring portion to align the selector.

5. The semiconductor memory device according to claim 1, wherein the first wirings include a conductive material having a thermal conductivity higher than a thermal conductivity of a silicon oxide film and a silicon nitride film.

6. The semiconductor memory device according to claim 1, wherein the second wirings each include a second wiring portion extending below the plurality of memory cells and a second protrusion portion protruding from the second wiring portion in a third direction that intersects the first and second directions between the plurality of variable resistance elements adjacent to each other in the second direction.

7. The semiconductor memory device according to claim 6, wherein
the variable resistance element includes a storage layer configured with a ferromagnetic body, a barrier layer configured with a non-magnetic body, and a reference layer configured with a ferromagnetic body, wherein the storage layer, the barrier layer, and the reference layer are stacked in the third direction, and wherein the second protrusion portion protrudes with a depth from the second wiring portion to align the barrier layer.

8. The semiconductor memory device according to claim 6, wherein
the selector of each memory cell is provided closer to the first wirings than the corresponding variable resistance element, and
the second protrusion portion protrudes with a depth from the second wiring portion to align the selector.

9. The semiconductor memory device according to claim 6, wherein the second wirings include a conductive material having a thermal conductivity higher than a thermal conductivity of a silicon oxide film and a silicon nitride film.

10. The semiconductor memory device according to claim 2, further comprising: a second insulating film provided between the first insulating film and the first protrusion portion.

11. The semiconductor memory device according to claim 6, further comprising: a second insulating film provided between the first insulating film and the second protrusion portion.

12. The semiconductor memory device according to claim 1, wherein the variable resistance element is a magnetoresistive effect element.

13. A method, comprising:
forming, over a plurality of second wirings extending in a second direction, a stack including at least a selector material, a storage layer, a barrier layer, and a reference layer;
patterning the stack based on a hard mask;
forming an insulating film to extend along sidewalls of the patterned stack; and
forming a first wiring extending in a first direction and including a protrusion portion to extend along the sidewalls of the patterned stack with the insulating film interposed therebetween.

14. The method according to claim 13, wherein the storage layer is configured with a ferromagnetic body, the barrier layer is configured with a non-magnetic body, and the reference layer is configured with a ferromagnetic body.

15. The method according to claim 13, wherein the storage layer, the barrier layer, and the reference layer form a variable resistance element.
